(19) United States
(12) Patent Application Publication
(10) Pub. No.: US 2024/0187770 A1
(43) Pub. Date: Jun. 6, 2024

(54) MONOLITHIC SOUND TRANSDUCER AND ENVIRONMENTAL BARRIER

(71) Applicant: Infineon Technologies AG, Neubiberg (DE)

(72) Inventors: Hutomo Suryo Wasisto, München (DE); Fabian Streb, Regensburg (DE); Sebastian Anzinger, Miesbach (DE); Marc Füldner, Neubiberg (DE); Dominic Maier, Pleystein (DE)

(21) Appl. No.: 18/512,395

(22) Filed: Nov. 17, 2023

(30) Foreign Application Priority Data
Dec. 1, 2022 (EP) 22210899.5

(51) Int. Cl. H04R 1/08; B81C 1/00; B82B 3/00; H04R 19/00; H04R 19/04

(52) U.S. Cl. CPC H04R 1/086; B81C 1/00547; B82B 3/0023; H04R 19/005; H04R 19/04; H04R 2201/003

(57) ABSTRACT

A method for manufacturing a MEMS microphone device with a monolithically integrated environmental barrier structure includes providing a substrate structure including a base substrate and an additional substrate material layer deposited on the base substrate, creating a micromechanical environmental barrier structure in the substrate structure by applying a microstructuring process, where the micromechanical environmental barrier structure is configured to let a first amount of air pass through while preventing a second amount of at least one of moisture, liquid, oil or solid environmental particles from passing through, and creating a MEMS sound transducer structure in the additional substrate material of the substrate structure by applying a microstructuring process.

This application claims the benefit of European Patent Application No. 22210899.5, filed on Dec. 1, 2022, which application is hereby incorporated herein by reference.

### TECHNICAL FIELD

Embodiments of the present disclosure relate to a micromechanical environmental barrier chip for providing a protection for microelectromechanical system (MEMS) microphones or MEMS speakers against ingress of environmental solid, gaseous and/or moist particles. Further embodiments relate to a manufacturing method thereof.

### BACKGROUND

Despite their wide employment in several acoustic applications like smartphones, true wireless (TWS) earphones, etc., current MEMS-based microphones can be prone to influences from dust particles, moisture, and other physical or chemical objects, which consequently can result in a lower robustness and shortened lifetime of the devices.

Typical solutions of microphones often rely on external and large environmental barriers (EBs) that are placed far away from the microphone chips, potentially leading to high production cost, large package size, low acoustic performance, and limited usage for applications.

### SUMMARY

In one aspect, a method for manufacturing a MEMS microphone device with a monolithically integrated environmental barrier structure is disclosed. The method includes providing a substrate structure including a base substrate and an additional substrate material layer deposited on the base substrate. The method further includes creating a microstructured micromechanical environmental barrier structure in the substrate structure by applying a microstructuring process, where the microstructured micromechanical environmental barrier structure is configured to let a first amount of air pass through while preventing a second amount of at least one of moisture, liquid, oil and solid environmental particles from passing through. The method further includes creating a MEMS sound transducer structure in the additional substrate material of the substrate structure by applying a microstructuring process, resulting in the MEMS sound transducer structure and the microstructured micromechanical environmental barrier structure being both monolithically integrated in the substrate structure.

### BRIEF DESCRIPTION OF THE DRAWINGS

In the following, embodiments of the present disclosure are described in more detail with reference to the figures, in which

FIG. 1 shows a schematic block diagram of a method for manufacturing a micromechanical environmental barrier chip according to an example,

FIGS. 2A-2C show a embodiments in a top view, a cross-sectional view and a perspective view, respectively, of an unprocessed substrate,

FIGS. 3A-3C show a further embodiment of applying a material layer on the substrate in a top view, a cross-sectional view and a perspective view, respectively, of the substrate,

FIGS. 4A-4C show a further embodiment of creating an environmental barrier structure on top of the material layer in a top view, a cross-sectional view and a perspective view, respectively, of the substrate,

FIGS. 5A-5C show a further embodiment of creating a cavity in the substrate in a top view, a cross-sectional view and a perspective view, respectively, of the substrate,

FIGS. 6A-6C show a further embodiment of applying nanofibers onto the environmental barrier structure in a top view, a cross-sectional view and a perspective view, respectively, of the substrate,

FIG. 7A shows a perspective view of an environmental barrier chip with nanofibers applied thereon,

FIG. 7B shows an exploded view of the environmental barrier chip of FIG. 7A,

FIG. 8A shows a top view onto the environmental barrier chip of FIG. 7A,

FIG. 8B shows a cross-sectional view along the cross-sectional line B-B in FIG. 8A,

FIG. 9A shows a top view onto the environmental barrier chip of FIG. 7A,

FIG. 9B shows a cross-sectional view along the cross-sectional line C-C in FIG. 9A,

FIG. 10 shows a cross-sectional view of an environmental barrier chip according to a further example,

FIG. 11 shows a sequence of embodiments for creating the environmental barrier chip of FIG. 10,

FIGS. 12A-12D show top views of an environmental barrier chip with micro beams according to examples,

FIG. 12E shows a cross-sectional view of the environmental barrier chip of FIG. 12A along the cross-sectional line F-F,

FIG. 12F shows a cross-sectional view of the environmental barrier chip of FIG. 12A along the cross-sectional line G-G,

FIG. 13 shows a cross-sectional view and a top view of an environmental barrier chip according to an example,

FIGS. 14A-14E show different packaging concepts,

FIG. 15A shows a perspective view of an environmental barrier chip according to an example,

FIG. 15B shows a picture of the environmental barrier chip taken with a raster electron microscope,

FIG. 15C shows a graphical illustration of a simulation for comparing square grid size against SNR loss,

FIG. 15D shows a further graphical illustration of a simulation for comparing square grid size against SNR loss,

FIG. 16 shows a schematic cross-sectional view of a MEMS microphone device with a monolithically integrated environmental barrier structure according to an embodiment,

FIG. 17 a schematic block diagram of a method for manufacturing a MEMS microphone device with a monolithically integrated environmental barrier structure according to an embodiment,

FIGS. 18A-18F show different cross-sectional views of different embodiments of MEMS microphone devices with a monolithically integrated environmental barrier structure, where the environmental barrier structure is created by surface micromachining,

FIGS. 19A-19F show different cross-sectional views of different embodiments of MEMS microphone devices with a monolithically integrated environmental barrier structure, where the environmental barrier structure is created by etching the base substrate, and

FIGS. 20A-20C show different cross-sectional views of different embodiments of MEMS microphone devices with a monolithically integrated environmental barrier structure and their possible configurations inside a package.

### DETAILED DESCRIPTION OF ILLUSTRATIVE EMBODIMENTS

Equal or equivalent elements or elements with equal or equivalent functionality are denoted in the following description by equal or equivalent reference numerals.

Method steps which are depicted in a block diagram and which are described with reference to the block diagram may be executed in an order different from the depicted and/or described order. Furthermore, method steps concerning a particular feature of a device may be replaceable with the feature of the device, and vice versa. Some method steps may be omitted or rearranged in different embodiments.

It would be desirable to provide a microstructured environmental barrier for MEMS-based acoustic elements, the environmental barrier including a small form factor while providing reliable and robust protection against ingress of environmental solid, gaseous and/or moist particles. It would further be desirable to provide a manufacturing method thereof that enables a reduction in production costs.

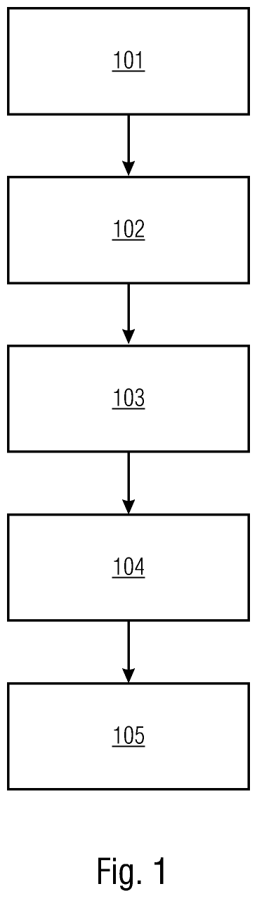

This description starts with an overview of an exemplary method for manufacturing a micromechanical environmental barrier structure using surface micromachining methods, which will be described in examples where the micromechanical environmental barrier structure may be created on a chip as a discrete component, i.e. an environmental barrier chip, with reference to FIGS. 1 to 15E.

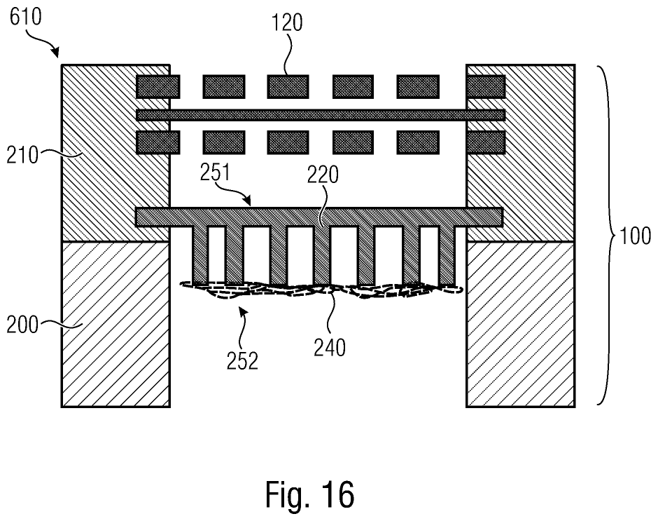

The description continues with various embodiments, where the environmental barrier structure is monolithically integrated together with a MEMS sound transducer structure (e.g. a membrane) in a common chip that may be referred to as a MEMS microphone device, and which embodiments are described with reference to FIGS. 16 to 20C.

The description with reference to FIGS. 1 to 15E may apply for the embodiments as described with reference to FIGS. 16 to 20C, and vice versa. In particular the method for manufacturing the environmental barrier structure, as described with reference to FIGS. 1 to 15E (discrete component), may be applied for manufacturing the monolithically integrated environmental barrier structure, as discussed with reference to FIGS. 16 to 20C. In particular, the features and examples as described with reference to FIGS. 1 to 15E may be combinable with the features and embodiments as discussed with reference to FIGS. 16 to 20C, and vice versa.

FIG. 1 shows a schematic block diagram of an exemplary method for manufacturing an environmental barrier chip including an environmental barrier structure.

In block 101, a substrate may be provided, the substrate having a first surface and an opposite second surface.

In block 102 a material layer may be deposited onto the first surface of the substrate, the material layer having a different etch characteristic than the substrate. An etch characteristic may include a certain selectivity. The selectivity describes an etch ratio between two different materials. For example, if the selectivity is 2:1, then a first material is etched/removed two times faster than a second material, when applying the same etching process for the same time duration on both materials.

In block 103 a microstructured micromechanical environmental barrier structure may be provided on top of the material layer by applying a microstructuring process.

In block 104 an anisotropic etching process may be performed including at least one etching step for anisotropically etching through the substrate (e.g., from the second surface towards the first surface of the substrate) until reaching the material layer so as to create at least a first cavity opposite (e.g., underneath) the micromechanical environmental barrier structure, the cavity extending between the second surface and the material layer.

In block 105 any of the material layer that resides inside the cavity may be removed in order to expose the environmental barrier structure.

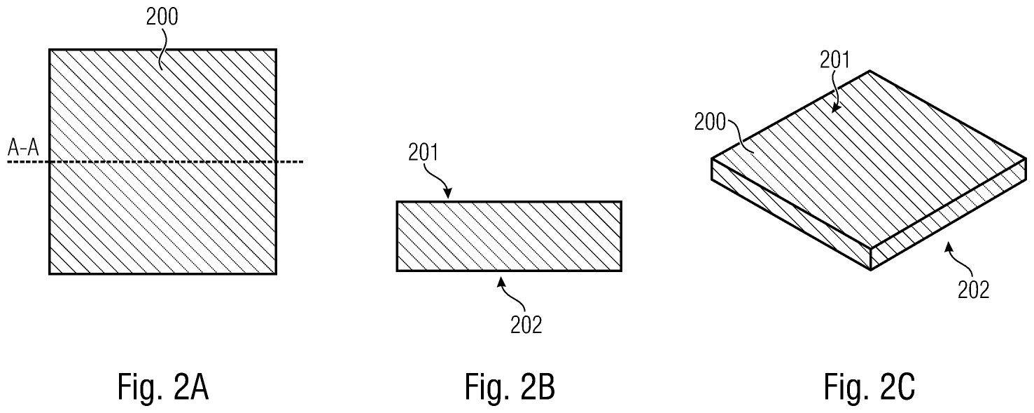

FIGS. 2A to 5C show a structural description of the above mentioned exemplary method. FIGS. 2A, 3A, 4A and 5A show a top view onto the substrate 200 to be processed. FIGS. 2B, 3B, 4B and 5B show a cross-sectional view along the section line A-A. FIGS. 2C, 3C, 4C and 5C show a perspective view of the substrate 200.

Starting with FIGS. 2A to 2C, a substrate 200 is depicted, the substrate 200 having a first surface 201 and an opposite second surface 202. The substrate 200 may be referred to as a base substrate. The substrate 200 may include, a semiconductor material, such as silicon, for example. The substrate 200 may include glass, (poly-)imide, plastics or the like. The substrate 200 may be flexible or rigid.

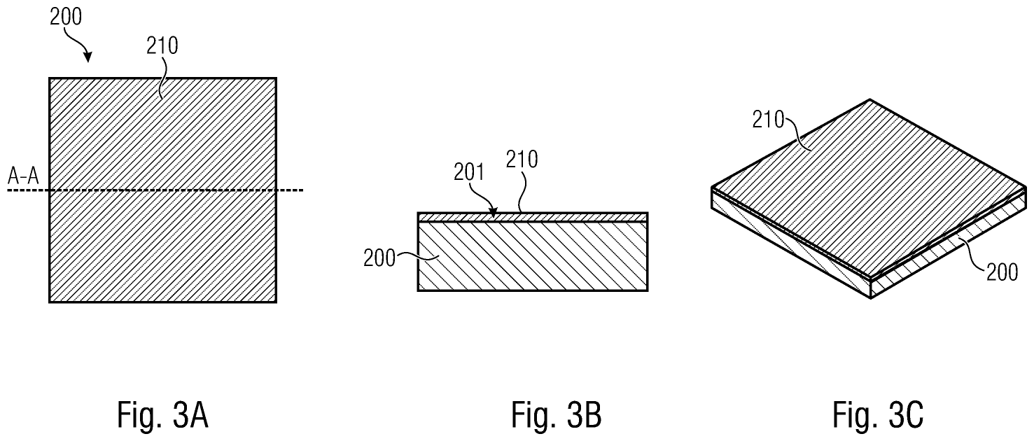

FIGS. 3A to 3C show a further embodiment in which a material layer 210 may be deposited onto the first surface 201 of the substrate 200. The material layer 210 may be referred to as an additional substrate material layer. The material layer 210 may be deposited completely over the entire first substrate surface 201. The material layer 210 may include a different etch characteristic than the substrate 200. For example, the material layer 210 and the substrate 200 may include a high selectivity for one and the same etchant. The selectivity describes the etch ratio between the material layer 210 and the substrate 200. For example, the substrate 200 may be etched/removed significantly faster than the material layer 210. In some embodiments, the substrate 210 may be completely removed while the material layer 210 is not noticeably etched/removed.

Accordingly, as will be explained in more detail below, the material layer 210 may serve the purpose of an etch stop layer. For example, the material layer 210 may include, tetraethyl orthosilicate, formally named tetraethoxysilane (TEOS), or other oxide (e.g., thermal silicon dioxides —SiO₂—, atomic layer deposited oxide) and nitride (e.g., silicon nitride) materials. These materials have an insulating characteristic. For example, the etch rate between TEOS (as the material layer 210) and silicon (substrate 200) is about 1:100, i.e., silicon is etched/removed a hundred times faster than TEOS.

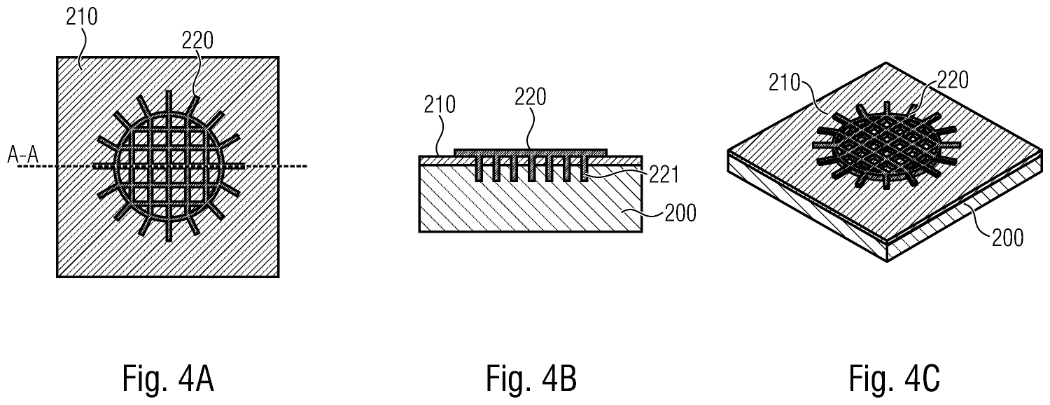

FIGS. 4A to 4C show further embodiments. A microstructured micromechanical environmental barrier structure 220 may be created on top of the material layer 210. The micromechanical environmental barrier structure 220 may be formed by applying a microstructuring process, e.g. a surface MEMS micromachining process. The micromechanical environmental barrier structure 220 may be provided as an air permeable mesh, as depicted, or as a perforated air permeable membrane.

The micromechanical environmental barrier structure 220 may include a circular or rectangular shape, while other geometrical shapes are possible. The micromechanical environmental barrier structure 220 may include vertically extending rib structures 221 that may extend through the material layer 210 and penetrate into the substrate 200, as shown in FIG. 4B. The rib structures 210 may be arranged in a cross-wise manner thereby creating a mesh structure.

The micromechanical environmental barrier structure 220 may be fabricated using wafer-level front-end processing. A main layer of the micromechanical environmental barrier structure 220 may include various materials used in front-end semiconductor processing, which include but are not limited to silicon, nitride, stacked silicon/nitride, and polymeric materials, e.g., polyimide, poly(methyl methacrylate) (PMMA), polydimethylsiloxane (PDMS), SU-8, and benzocyclobutene (BCB). The micromechanical environmental barrier structure 220 may be rigid and may provide sufficient large hole openings (e.g., 10 μm to 40 μm) to avoid high loss of signal-to-noise ratio (SNR) and sensitivity.

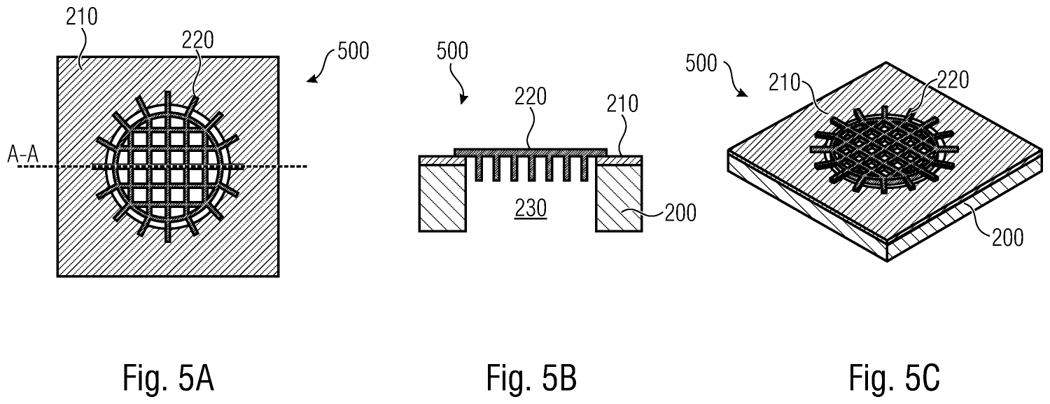

FIGS. 5A to 5C show further embodiments. An anisotropic etching process, e.g. Reactive Ion Etching (RIE) using a Bosch etching process, may be applied including at least one etching step for anisotropically etching from the second surface 202 towards the first surface 201 of the substrate 200 so as to create at least a first cavity 230 underneath (i.e. opposite to) the micromechanical environmental barrier structure 220. The cavity 230 may extend completely through the substrate 200. Therefore, the cavity 230 may be referred to as an opening or a through hole.

The material layer 210 may serve as an etch stop layer. Accordingly, the substrate 200 may be etched until the etchant reaches the material layer 210. Even though not explicitly shown in FIGS. 5A to 5C, some of the material layer 210 may remain underneath the micromechanical environmental barrier structure 220, i.e. it may remain between the micromechanical environmental barrier structure 220 and the cavity 230.

FIGS. 5A to 5C show an embodiment, in which the material layer 210 underneath the micromechanical environmental barrier structure 220 was already removed such that the micromechanical environmental barrier structure 220 is already exposed. However, in some embodiments portions of the material layer 210 underneath the micromechanical environmental barrier structure 220 may be removed, as shown in FIGS. 5A to 5C, while the rest of the deposited material layer 210 may remain on the first surface 201 of the substrate 200.

After removal of the material layer 210 underneath the micromechanical environmental barrier structure 220, as shown in FIG. 5B, the micromechanical environmental barrier structure 220 is exposed, i.e. it is in direct fluid contact with the cavity 230. Accordingly, fluids, and in particular gaseous fluids like ambient air, may flow through the cavity 230 and pass the micromechanical environmental barrier structure 220.

The micromechanical environmental barrier structure 220 may be configured to let a first amount of air pass through while preventing a second amount of at least one of moisture, liquids, oil and solid environmental particles from passing through.

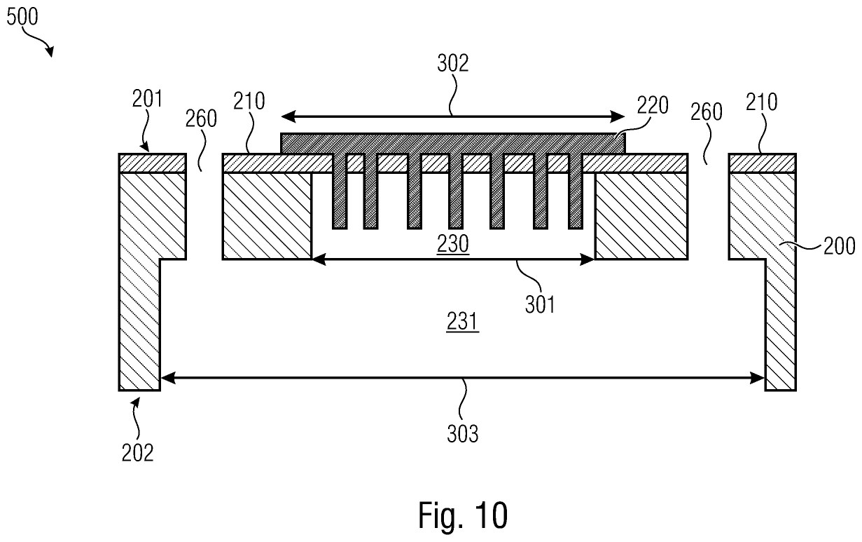

FIG. 5C shows the resulting device, namely a micromechanical environmental barrier chip 500 including a microstructured micromechanical environmental barrier structure 220 suspended over a through hole or cavity 230 formed in a substrate 200. As will be explained in more detail below, the herein described method allows for a very thin micromechanical environmental barrier chip 500, which is described with reference to FIGS. 10 to 13.

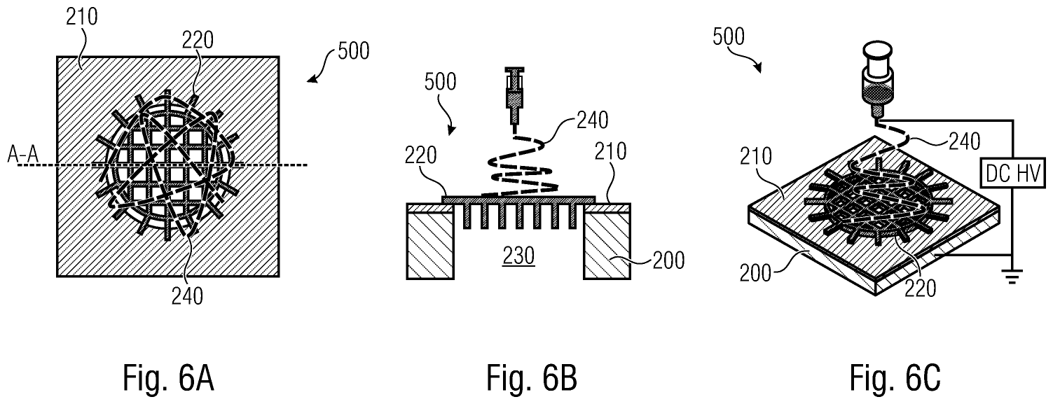

Meanwhile, referring to FIGS. 6A to 6C showing further embodiments, nanofibers 240 may be deposited on the fabricated micromechanical environmental barrier chip 500, and in particular, on the environmental barrier structure 220. The nanofibers 240 may include, different polymers, e.g., polyvinylidene fluoride (PVDF), polyacrylonitrile (PAN), polyvinyl chloride (PVC), polytetrafluoroethylene (PTFE), polyethylene (PE), and polyaniline (PANI).

The nanofibers 240 may be deposited by using electrospinning techniques. Various electrospinning methods can be used, including needleless electrospinning, multi-jet electrospinning, cylindrical porous hollow tube electrospinning, bubble electrospinning, coaxial electrospinning, melt electrospinning, force-spinning, flash-spinning, self-bundling electrospinning, nanospider electrospinning, and charge injection electrospinning.

For example, electrospun nanofibers 240 may possess superhydrophobic characteristics and may provide a self-cleaning effect (lotus effect). Surface chemistry modification by organic self-assembled monolayers (SAMs), stearic acid-based modifiers, and nanoparticles (e.g., Ag, SiO₂, and TiO₂) can be carried out to further lower the surface energy of the roughened nanofiber surfaces resulting in improved hydrophobicity. The SAMs may include fluoroalkylsilanes (FAS), perfluorodecyltrichlorosilane (FDTS), and methyltrimethoxysilane (MTMS).

Accordingly, embodiments of the herein described method may include applying a surface chemistry modification to the applied nanofibers 240 by depositing at least one of
organic self-assembled monolayers,
stearic acid-based modifiers, and
nanoparticles
onto the nanofibers 240 for lowering the surface energy of the nanofibers 240 resulting in an increased hydrophobicity.

Besides the above mentioned exemplary components, the organic self-assembled monolayers may comprise at least one of:
Perfluorodecyltrichlorosilane (FDTS),
Heptadecafluoro-1,1,2,2-tetrahydrodecyltrichlorosilane (HDFS),
Tridecafluoro-1,1,2,2-tetrahydrooctyltrichlorosilane (FOTS),
Octadecyltrichlorsilane (ODTS),
Methyltrimethoxysilane (MTMS),
Bis(trimethylsilyl)amine or hexamethyldisilazane (HMDS),
(3-Aminopropyl)triethoxysilane (APTES),
Dichlorodimethylsilane (DDMS),
Octadecyltrimethoxysilane (OTMS),
Ethyltriethoxysilane (ETES), and
1H,1H,2H,2H-perfluorooctyltriethoxysilane (HFOTES).

As mentioned above, the micromechanical environmental barrier chip 500 disclosed herein may be used with micromechanical MEMS-based acoustic components, like MEMS microphones, MEMS speaker or the like. To maintain a high SNR (Signal-to-Noise Ratio) of the MEMS-based acoustic components, and at the same time to provide a good environmental robustness towards particles and water, a thin layer of nanofibers 240 may be deposited allowing high airflow through the holes or pores of the micromechanical environmental barrier structure 220.

To improve the adhesion between the applied nanofibers 240 and the micromechanical environmental barrier structure 220, several strategies can be applied, e.g. insertion of an adhesion promoter as a middle layer between the applied nanofibers 240 and the micromechanical environmental barrier structure 220, increasing the surface roughness of the micromechanical environmental barrier structure 220, or a three-dimensional (3D) modification of the micromechanical environmental barrier structure 220.

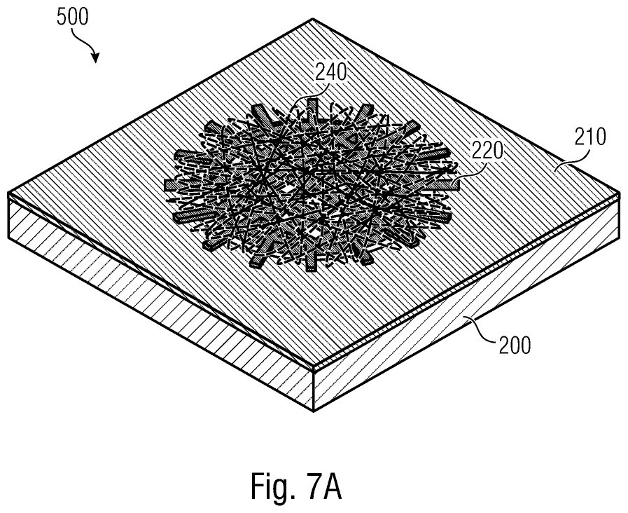

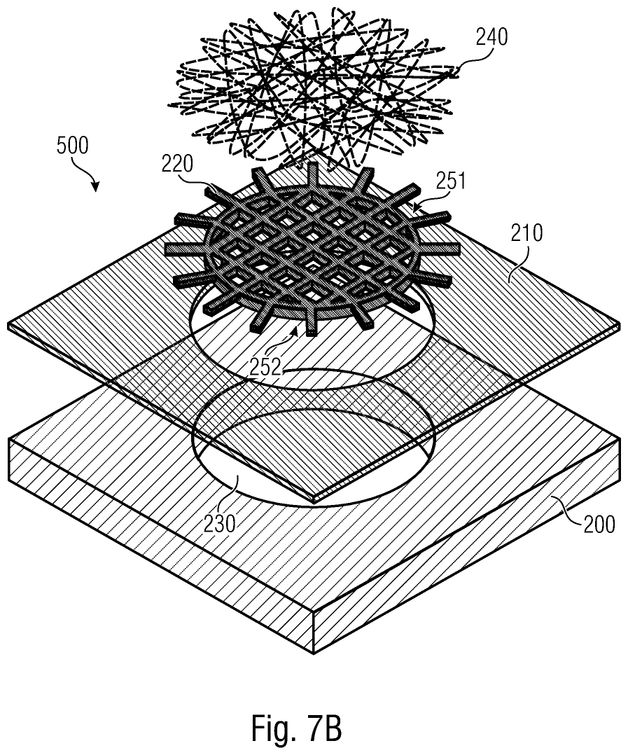

As shown in FIGS. 7A and 7B, the nanofibers 240 may be applied onto the micromechanical environmental barrier structure 220 such that the nanofibers 240 combine to form an air permeable nanofibrous membrane structure. Therefore, the nanofibers 240 can support the environmental barrier structure 220 in its functionality, i.e. to let a first amount of air pass through while preventing a second amount of at least one of moisture, liquids, oil and solid environmental particles from passing through.

The nanofibers 240 may be applied on either one of a first side 251 (top) or a second side 252 (bottom) of the micromechanical environmental barrier structure 220. The nanofibers 240 may be applied on both the first and second sides 251, 252 (top and bottom) of the micromechanical environmental barrier structure 220.

Accordingly, the method disclosed herein may allow to manufacture a MEMS-based mesh chip 500 integrated with a nanofiber membrane 240. As shown in FIG. 7B, the micromechanical environmental barrier chip 500 may include a substrate 200 (e.g. a silicon substrate), having a through hole 230 formed therein. The through hole 230 extending between the first substrate surface 201 and the opposite second substrate surface 202 completely through the substrate 200. An additional material layer 210 (e.g. an etch stop layer including TEOS) may be deposited at the first substrate surface 201. In the final device 500, the through hole 230 may extend through the material layer 210. A micromechanical environmental barrier structure 220 (e.g. a MEMS-based mesh or membrane) may be arranged at the first substrate surface 201, in particular at the additional material layer 210. The micromechanical environmental barrier structure 220 may be suspended over the through hole 230. Nanofibers 240 may be applied onto the micromechanical environmental barrier structure 220, e.g. by electrospinning techniques. The applied nanofibers 240 may combine to form a nanofibrous mat or a nanofiber membrane.

Some materials used for the fabrication of nanofibers 240 (e.g. some polymers) may include less optimal adhesion characteristics for adhering the nanofibers 240 to the environmental barrier structure 220 and/or to the substrate 200, which may be an issue if an air flow with high air pressure passes through the MEMS-based mesh chip 500. If the nanofibers 240 are not properly fixed to the environmental barrier structure 220, then the nanofibers 240 may be swept away. To keep the nanofibers 240 stable on their position after deposition (i.e., to increase the stability of the nanofibers 240 at higher air pressure), one or more additional layers having a geometrical shape including, for instance, a frame or a ring structure, may be applied on top of the nanofibers 240. Hence, the additional layer(s) (e.g., metal) can hold or fix the nanofibers 240.

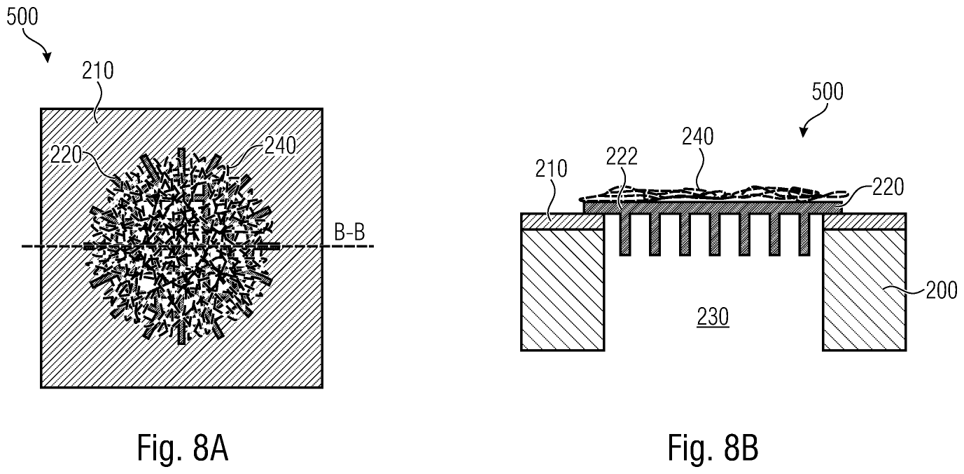

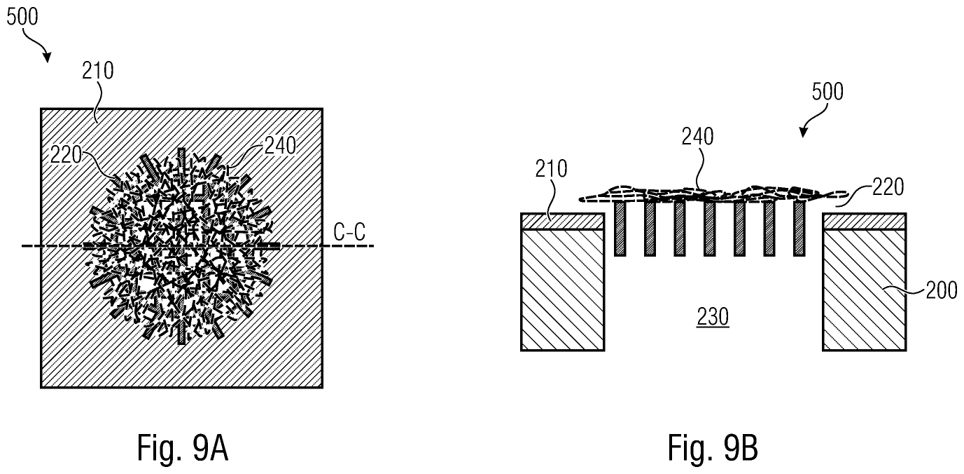

FIGS. 8A to 9B show some possible implementations and examples of an environmental barrier chip 500 with an integrated environmental barrier structure 220 and an additional nanofiber membrane 240. FIG. 8B shows a cross-sectional view across the sectional line B-B shown in FIG. 8A. FIG. 9B shows a cross-sectional view across the sectional line C-C shown in FIG. 9A. As can be seen, the nanofibers 240 may be applied randomly crosswise over the environmental barrier structure 220. The nanofibers 240 may be applied in multiple passes creating a nanofiber structure (e.g. membrane or mat) including multiple layers of stacked nanofibers 240 being arranged one atop the other, as shown in FIGS. 8B and 9B. The nanofibers 240 may extend over the horizontal ribs 222 (FIG. 8B) which form the mesh of the environmental barrier structure 220, and the nanofibers 240 may extend over the holes between the horizontal ribs 222 (FIG. 9B).

The process as described herein may be performed at wafer-level, where the substrate 200 may be a wafer from which a plurality of the above described micromechanical environmental barrier chips 500 can be produced. In the wafer-level process, the method may further include singulating (e.g., by dicing) the plurality of micromechanical environmental barrier chips 500 from the wafer.

For facilitating the singulation process and enabling a pick-and-place joining method of the environmental barrier chip 500 onto a printed circuit board (PCB) used in acoustic component packaging (e.g., for MEMS microphone packages), a device separation concept disclosed herein describes thin microplates or microbeams between the single environmental barrier chips 500.

A non-limiting example is depicted in FIG. 10. Even though not explicitly shown, the material layer 210 underneath the environmental barrier structure 220 may be removed, as discussed above. The cavity 230 is shown, which is referred to as a first cavity in the following. The first cavity 230 may include a lateral extension 301 that is equal to or smaller than the outer contour 302 (e.g. outer diameter) of the micromechanical environmental barrier structure 220. As indicated by arrows 301, 302, 303, the lateral extension is to be measured in-plane of the chip 500, i.e. orthogonally to the substrate thickness between the first and second substrate surfaces 201, 202. In the example of FIG. 10, applying the anisotropic etching process may further include an anisotropic etching step for anisotropically etching from the second substrate surface 202 towards the first substrate surface 201 so as to create a second cavity 231 in the substrate 200. The second cavity 231 may include a larger lateral extension 303 than the first cavity 230.

Applying the anisotropic etching process may include a further anisotropic etching step for anisotropically etching a plurality of discontinuous trenches 260 into the substrate 200, and may etch into the material layer 210. The plurality of discontinuous trenches 260 may vertically extend between the first substrate surface 201 and the second cavity 231. The plurality of discontinuous trenches 260 may laterally surround the micromechanical environmental barrier structure 220.

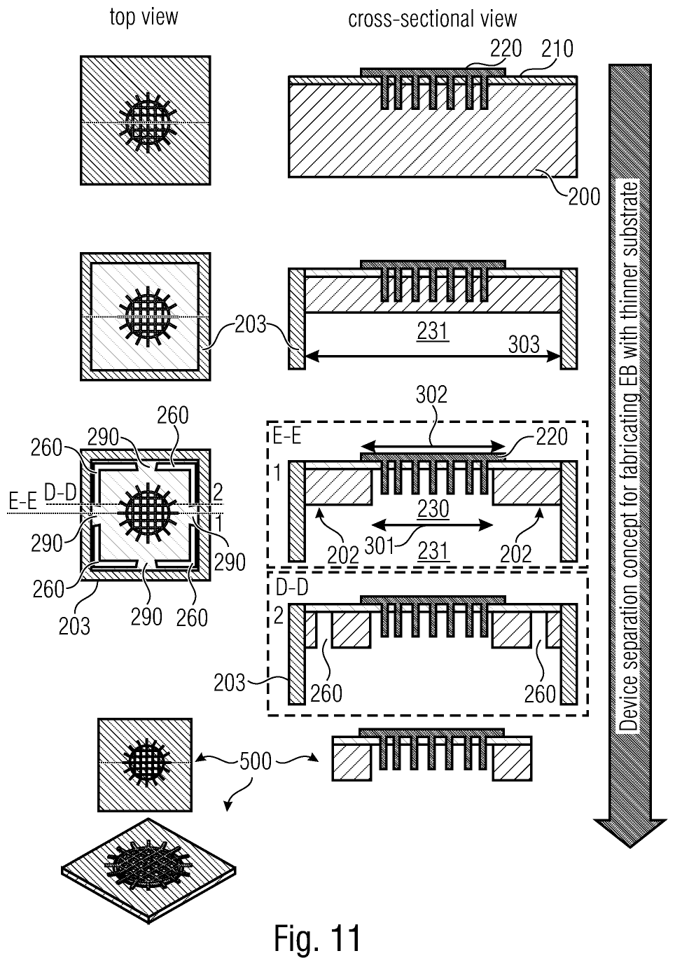

The term ‘discontinuous’ refers to the trenches 260 being incompletely or discontinuously formed around the environmental barrier structure 220, i.e., the trenches 260 may not fully surround the environmental barrier structure 220. Instead, some portions of substrate material may be left in between, such that the trenches 260 are separated from each other. These remaining portions of substrate material may form micro beams that hold the environmental barrier chip 500 on the substrate 200 prior to singulating it (e.g., by dicing), which is further explained with reference to FIG. 11.

FIG. 11 shows, from top to bottom, embodiments for creating the above mentioned micro beams 290. The left hand side shows top views of the environmental barrier chip 500, while cross sectional views are shown on the right.

Starting from the uppermost picture row in FIG. 11, the unprocessed substrate 200 is shown. The additional material layer 210 (e.g. TEOS) is deposited at the first substrate surface 201, and the environmental barrier structure 220 is arranged on top of the material layer 210. The upper picture row in FIG. 11 shows the fabrication of the micromechanical environmental barrier structure 220 by processing a main layer using surface MEMS micromachining methods. The environmental barrier structure 220 may be created as either a mesh or a membrane. In FIG. 11, a mesh is shown as an example. In some embodiments, nanofibers may be applied onto the environmental barrier structure 220. In case of a membrane, small ventholes may be provided absent a grid to enable airflow coming from the package sound port.

The second picture row (from top) in FIG. 11 shows an embodiment of applying the anisotropic etching process which may include applying an anisotropic etching step, e.g. Reactive Ion Etching (RIE) using Bosch etching process, for anisotropically etching a cavity 231 into the substrate 200. This cavity 231 may correspond to the above described second cavity 231. As indicated by cross-hatched lines, the lateral/circumferential remaining portions 203 of the substrate 200, where the second cavity 231 was not formed, may be thicker than the rest of the substrate 200, where the second cavity 231 was formed. In other words, the substrate 200 is thinned in an area, where the cavity 231 is formed. The second cavity 231 may include a larger lateral extension 303 than the first cavity 230, that may be formed in a next step.

Referring now to the third and fourth picture row (from top) in FIG. 11, the third picture row shows a top view of the environmental barrier chip 500 on the left, and a cross-sectional view along the cross sectional line E-E on the right. The fourth picture row shows a cross-sectional view along the cross sectional line D-D.

As can be seen in the third picture row (from top) in FIG. 11, a further cavity 230 is etched into the substrate 200 by applying an anisotropic etching step, e.g. Reactive Ion Etching (RIE) using Bosch etching process. This further cavity 230 may correspond to the above described first cavity 230 that is etched from the second substrate surface 202 up to the material layer 210, e.g. TEOS as an etch stop layer. Since the substrate 200 is thinned in this area, as mentioned above, the second substrate surface 202 may be the substrate surface of the thinned substrate 200, as shown in the picture. That is, the first cavity 230 may be etched into the thinned substrate 200, from the second surface 202 of the thinned substrate 200 up to the material layer 210. The first cavity 230 may include a lateral extension 301 that is equal to or smaller than the outer contour 302 (e.g. outer diameter) of the micromechanical environmental barrier structure 220.

As can further be seen in the third and fourth picture rows (from top) in FIG. 11, the anisotropic etching process may further include anisotropically etching a plurality of discontinuous trenches 260 into the thinned substrate 200, which may be performed at the same time as the above described creation of the first cavity 230, i.e., the first cavity 230 and the discontinuous trenches 260 may be created with the anisotropic etching process. As can be seen in the fourth picture row, the plurality of discontinuous trenches 260 may vertically extend between the first substrate surface 201 and the second cavity 231. That is, the discontinuous trenches 260 may be etched into the thinned portions of the substrate 200. As can best be seen in the top view of the third picture row, the plurality of discontinuous trenches 260 may laterally surround the micromechanical environmental barrier structure 220.

As mentioned above, the term ‘discontinuous’ refers to the trenches 260 being incompletely or discontinuously formed around the environmental barrier structure 220, i.e. the trenches 260 may partially surround the environmental barrier structure 220, such that some portions of substrate material 290 may be left in between, and the trenches 260 are separated from each other. These remaining portions of substrate material may form micro beams 290 that hold the environmental barrier chip 500 on the substrate 200 prior to singulating the substrate 200, e.g. by dicing.

Accordingly, etching the plurality of discontinuous trenches 260 may include of leaving portions 290 of substrate material (in some embodiments with the material layer 210 on top) between the plurality of discontinuous trenches 260, such that these portions 290 form micro beams 290 which structurally connect the micromechanical environmental barrier chip 500 on one side of the plurality of discontinuous trenches 260 with the substrate 200 on an opposite other side of the plurality of discontinuous trenches 260.

Since the micro beams 290 are formed in the thinned substrate 200, the micro beams 290 may include the same thickness as the thinned substrate 200. Accordingly, the remaining thicker lateral/circumferential portions 203 (cross-hatched lines) of the substrate 200 may provide a frame structure at which the thinned substrate 200 may be suspended by the micro beams 290. Since the micro beams 290 include the same thickness as the thinned substrate 200, the micro beams 290 can easily be broken/ruptured in order to singulate a single environmental barrier chip 500 from the substrate 200 during a pick-and-place process, in particular in case the substrate 200 is provided as a wafer. The last picture row (from top) shows a singulated environmental barrier chip 500.

Accordingly, the plurality of discontinuous trenches 260 may define the lateral size of the final micromechanical environmental barrier chip 500. In other words, the above described etching steps may deem to define the final chip size after singulating the chip 500, as well as to create the thin micro beams 290 for separating the environmental barrier chip 500. The separation of the environmental barrier chip 500 from the wafer 200 may be done by using pick-and-place joining techniques. As a final device, a MEMS environmental barrier chip 500 on a thinned substrate 200 can be realized.

To create the thinned mechanical supporting substrate 200, a double Bosch etching process may be applied for creating the above described first and second cavities 230, 231, which may be beneficial to avoid high SNR loss affected by a reduced back volume inside a lid of a MEMS microphone system, for example. A typical thickness of an initial unprocessed substrate 200, that may be used to create an environmental barrier structure 220 as described herein, may be between 200 μm and 500 μm, and preferably between 300 μm and 400 μm. Using anisotropic etching, e.g. a double Bosch etching process, the final environmental barrier chip 500 may include a thickness (i.e. height) between 20 μm and 150 μm, and preferably between 30 μm and 60 μm, depending on the used reactive ion etching (RIE) process parameters, especially the etching duration.

Accordingly, the unprocessed initial substrate 200 (prior to applying the anisotropic etching process) may include a thickness between 200 μm and 500 μm. By applying the anisotropic etching process, the second cavity 231 may be formed such that a thinned remaining portion of the substrate 200 results that includes a thickness between 20 μm to 150 μm and which defines the final thickness of the environmental barrier chip 500.

Even though not explicitly shown in FIG. 11, any of the material layer 210 underneath the environmental barrier structure 220 may be removed, as discussed above. Furthermore, the etching steps for forming the first and second cavities 230, 231, respectively, may be swapped regarding its temporal execution, i.e. the smaller first cavity 230 may be created first, before creating the larger second cavity 231 afterwards.

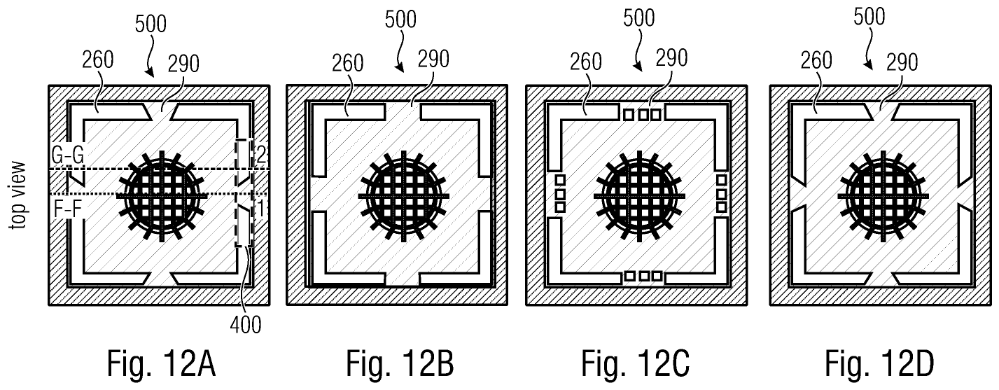

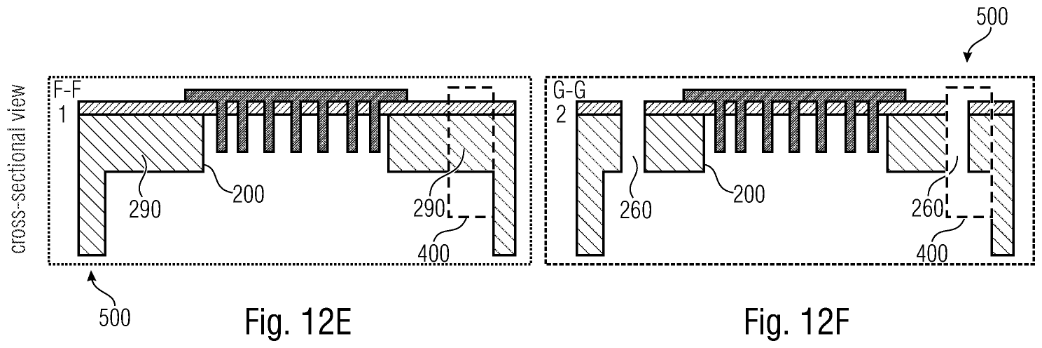

As shown in FIGS. 12A to 12F, various designs of micro beams 290 may be created resulting in optimized device breaking performance during the pick-and-place process. These may include but are not limited to rectangular micro beams 290 (FIG. 12B), trapezoidal beams (FIG. 12A), round-edged trapezoidal micro beams 290 (FIG. 12D), and perforation-integrated beams (FIG. 12C). In case of trapezoidal micro beams, the smaller region is located at the inner part close to the active area of the membrane.

In the non-limiting examples shown in FIGS. 12A to 12F, the micro beams 290 are located approximately in the center of each of the four lateral sides of the environmental barrier chip 500. In some embodiments, one or more micro beams 290 may be located at different positions, e.g., at one or more corner regions of the environmental barrier chip 500.

Accordingly, the micro beams 290 may include at least one of the following geometrical shapes:
a trapezoidal shape,
a rectangular shape,
a round-edged trapezoidal shape, and
a geometrical shape including one or more perforations.

Summarizing, FIGS. 12A to 12D show different designs of micro beams 290 for breaking the device 500 from the wafer 200. The micro beams 290 may be created in various shapes to optimize the separation process.

FIG. 12E shows a cross-sectional view along line F-F in FIG. 12A. FIG. 12F shows a cross-sectional view along line G-G in FIG. 12A. The rectangle 400 drawn in dashed lines marks the micro beams 290 (FIG. 12E) and the trenches 260 (FIG. 12F), respectively, in the thinned substrate 200.

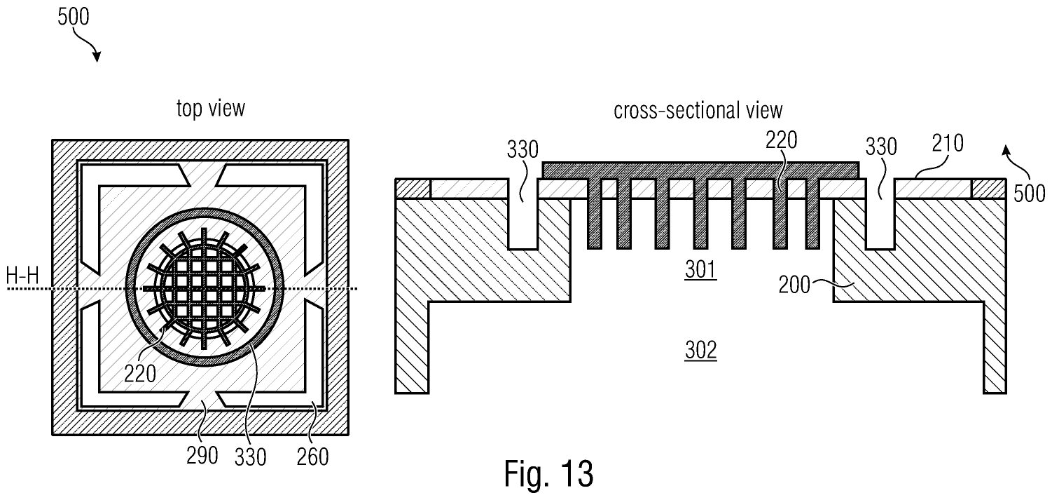

FIG. 13 shows a further embodiment of an environmental barrier chip 500, where a top view of the environmental barrier chip 500 is shown on the left side, while a cross-sectional view of the environmental barrier chip 500 along the cross-section line H-H is depicted on the right.

Additional stopping structures 330 (e.g., microwalls or microtrenches) may be created on the edge of the mechanical supporting substrate 200 to avoid adhesive (glue) to reach the environmental barrier structure 220, e.g., an active membrane area, during the joining process. The additional stopping structures 330 may be provided as a continuous trench, as exemplarily depicted.

Accordingly, the method may include etching a continuous trench 330 into the substrate 220 (and in some embodiments into the material layer 210). As can best be seen in the top view, the continuous trench 330 may laterally surround the micromechanical environmental barrier structure 220. In some embodiments, the trench 330 may be discontinuous. The trench 330 may include a circular shape, while other geometrical shapes may be possible.

Even though the stopping structure 330 is depicted in combination with the above discussed micro beams 290, the stopping structure 330 for trapping the adhesive may be provided in each of the other embodiments that may not necessarily include the micro beams 290 and/or the discontinuous trenches 260.

However, in case the micro beams 290 and/or discontinuous trenches 260 are available, then the stopping structure 330 (e.g. trench) may be located laterally between the micromechanical environmental barrier structure 220 and the micro beams 290, as shown in the top view of FIG. 13. The stopping structure 330 may include a circular shape.

Accordingly, the method may include creating a circular trench 330 for stopping the bleeding of any applied adhesive (e.g., glue, solder paste, or the like) during a joining process between the environmental barrier chip 500 and a further acoustic component, such as a MEMS microphone chip. The protecting trench concept using circular trench 330 may be an additional feature for the joining technique that involves the environmental barrier chip 500 placed inside a lid of a sound component package, such as a MEMS microphone package, in particular if the environmental barrier chip 500 may be placed underneath the MEMS microphone chip.

As mentioned above, the process as described herein may be performed at wafer-level, where the substrate 200 may be a wafer from which a plurality of the above described micromechanical environmental barrier chips 500 may be singulated. In the wafer process, the method may further include singulating (e.g. by dicing) the plurality of micromechanical environmental barrier chips 500 from the wafer 200. For example, the micromechanical environmental barrier chips 500 may be fabricated using wafer-level front-end processing. Accordingly, the micromechanical environmental barrier chip 500 may be integrated to the frontend chip, instead of manufacturing environmental barriers as individual devices. As a result, an acoustic component (e.g. a MEMS-microphone) can be provided with an integrated environmental barrier chip 500 directly in one and the same package, which may provide for a low-cost packaging solution for microphones with higher robustness against ingress of environmental solid, gaseous and/or moist particles.

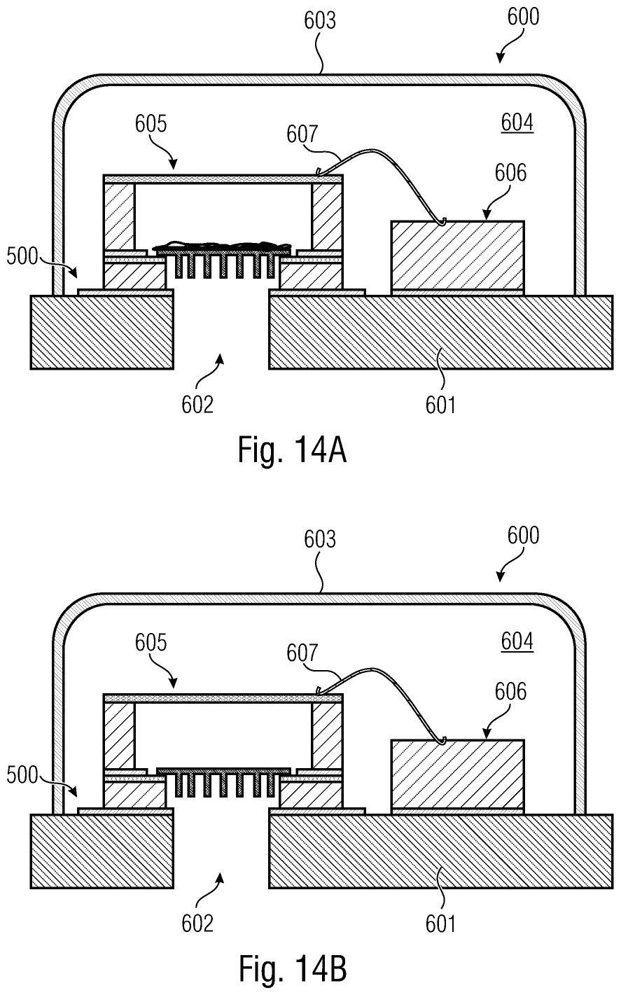

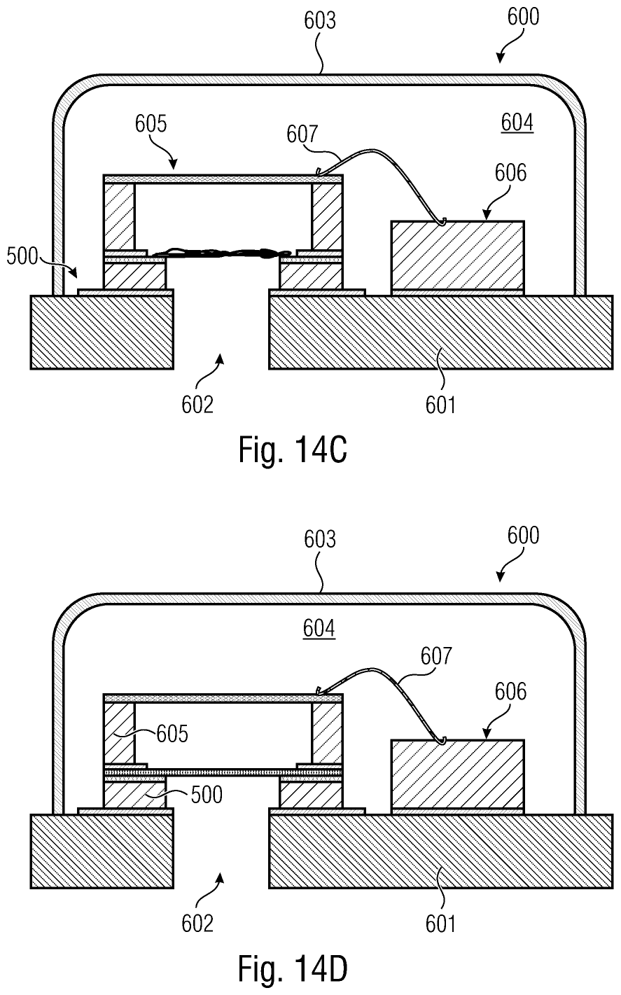

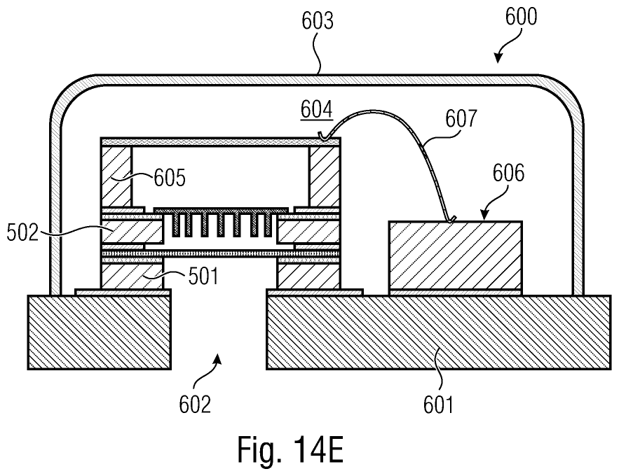

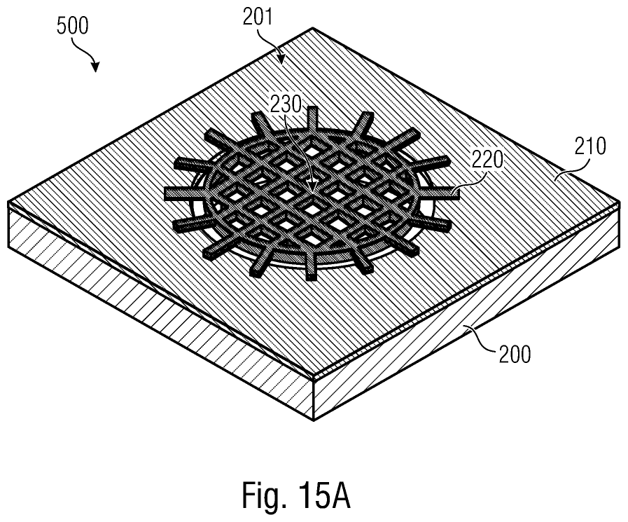

Furthermore, the above described versatile device separation concept (by micro beams 290) may be applied for passive environmental barrier structures 220 (e.g. membrane, mesh, nanofiber membrane-integrated mesh chips), and for active MEMS devices like microphones, pressure sensors, and others. The created environmental barrier chip 500 based on the micro beam 290 separation method can be mounted into a microphone package in different architectures, as will be explained in more detail with reference to FIGS. 14A to 14E. The created environmental barrier chip 500 may include a single environmental barrier structure 220 (e.g. environmental barrier mesh, environmental barrier membrane, or environmental barrier nanofibers) or joint environmental barrier elements (e.g. a nanofiber membrane-integrated mesh chip or environmental barrier membrane-stacked environmental barrier mesh chip).

FIGS. 14A to 14E show some non-limiting examples of packaging concepts for the micromechanical environmental barrier chip 500 according to the herein described principle. The package 600 may include a carrier substrate 601, e.g. a PCB, including a sound port opening 602. The package 600 may further include a cover or lid 603 being arranged on the substrate 601. The lid 603 provides a cavity 604 inside of which different electrical and/or electronic components may be arranged.

In the non-limiting example of FIGS. 14A to 14E, a MEMS microphone chip 605 may be arranged inside the cavity 604. Additionally, the herein described micromechanical environmental barrier chip 500 may be arranged inside the cavity 604. Furthermore, a circuitry 606 may be arranged inside the cavity 604. The circuitry 606 may be provided as an integrated circuit (IC), for instance as an ASIC (Application Specific Integrated Circuit). The circuitry 606 may be electrically connected to the MEMS microphone chip 605, for example by bond wires 607.

As shown in FIGS. 14A to 14E, the environmental barrier chip 500 may be arranged directly opposite the sound port 602 such that the environmental barrier chip 500 is in direct fluid communication with the sound port 602. In the environmental barrier chip 500, environmental solid, gaseous and/or moist particles may be prevented from entering the cavity 604 of the package 600. The MEMS microphone chip 605 may be stacked directly atop the environmental barrier chip 500. Thus, the environmental barrier chip 500 prevents environmental solid, gaseous and/or moist particles from reaching (and possibly destroying) the sensitive membrane of the MEMS microphone 605.

The environmental barrier chip 500 may be attached to the carrier substrate 601 by using adhesive, e.g. glue. In some embodiments, the MEMS microphone chip 605 may be attached to the environmental barrier chip 500 by using an adhesive, e.g. glue.

FIG. 14A shows an exemplary packaging concept in which the environmental barrier chip 500 includes an environmental barrier structure 220 formed as a micro machined mesh, in combination with nanofibers 240, as described with reference to FIGS. 6A to 7A. FIG. 14A shows a nanofiber-integrated environmental barrier mesh chip 500 arranged inside the package 600.

FIG. 14B shows a further exemplary packaging concept in which the environmental barrier chip 500 includes an environmental barrier structure 220 formed as a micro machined mesh without nanofibers, as described with reference to FIGS. 2A to 5C. FIG. 14B shows an environmental barrier mesh chip 500 without nanofibers arranged inside the package 600.

FIG. 14C shows a further exemplary packaging concept in which the environmental barrier chip 500 includes an environmental barrier structure 220 formed as a nanofibrous membrane or nanofibrous mat, which may be fabricated from deposited nanofibers 240. It is noted that embodiments of the environmental barrier structure 220 as described herein may be formed as a nanofibrous membrane or nanofibrous mat, which may be fabricated from deposited nanofibers 240, and may be absent a micromachined mesh or a membrane. FIG. 14C shows an environmental barrier nanofiber membrane chip 500 arranged inside the package 600.

FIG. 14D shows a further exemplary packaging concept in which the environmental barrier chip 500 includes an environmental barrier structure 220 formed as a membrane. It is noted embodiments of the environmental barrier structure 220 as described herein may be formed as a membrane instead of a micromachined mesh. The membrane 220 may be plane or structured with high compliance. Nanofibers may in some embodiments be deposited on membrane 220. FIG. 14D shows an environmental barrier membrane chip 500 with a membrane made from material other than nanofibers arranged inside the package 600.

FIG. 14E shows a further exemplary packaging concept in which two environmental barrier chips 501, 502 may be stacked one atop the other. A first environmental barrier chip 501 may include a microstructured mesh (with or without nanofibers deposited thereon). A second environmental barrier chip 502 may include a membrane (with or without nanofibers deposited thereon). One of the first and second environmental barrier chips 501, 502 may be arranged on the carrier substrate 601 opposite the sound port 602. The other one of the first and second environmental barrier chips 501, 502 may be stacked atop the bottom one. The MEMS microphone chip 605 may be stacked atop the first and second environmental barrier chips 501, 502. FIG. 14E shows a membrane-stacked mesh chip 500 arranged inside the package 600.

According to such an embodiment, the method may further include packaging the micromechanical environmental barrier chip 500 by mounting the micromechanical environmental barrier chip 500 together with a MEMS microphone chip 605 onto a carrier substrate 601, and arranging a package lid 603 on the carrier substrate 601, such that the package lid 603 covers and encloses the micromechanical environmental barrier chip 500 and the MEMS microphone chip 605.

According to a further example, the micromechanical environmental barrier chip 500 may be directly attached to the carrier substrate 601, where the MEMS microphone chip 605 is directly attached on top of the micromechanical environmental barrier chip 500, thereby forming a chip stack in which the micromechanical environmental barrier chip 500 is positioned between the MEMS microphone chip 605 and the carrier substrate 601.

According to a further example, the carrier substrate 601 may include a sound port opening 602, where the micromechanical environmental barrier chip 500 faces the sound port opening 602, such that the environmental barrier chip 500 is in fluid communication with the sound port opening 602.

According to a further example, the micromechanical environmental barrier chip 500 and the MEMS microphone chip 605 may be provided as two separate discrete components.

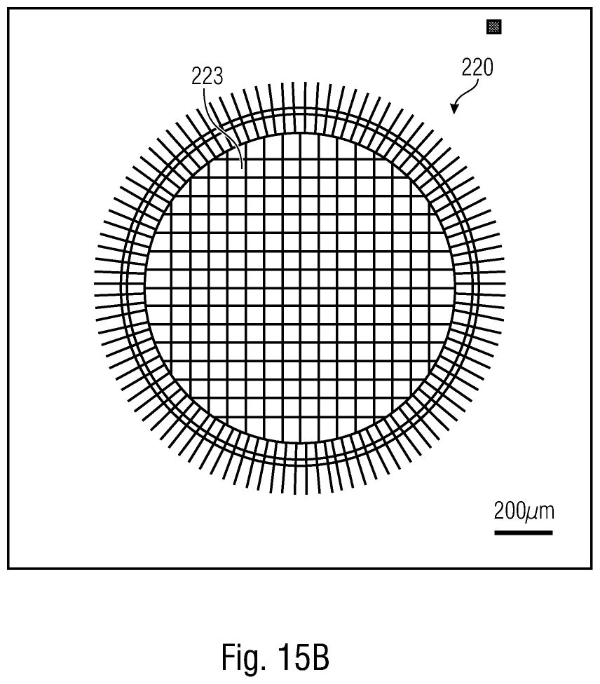

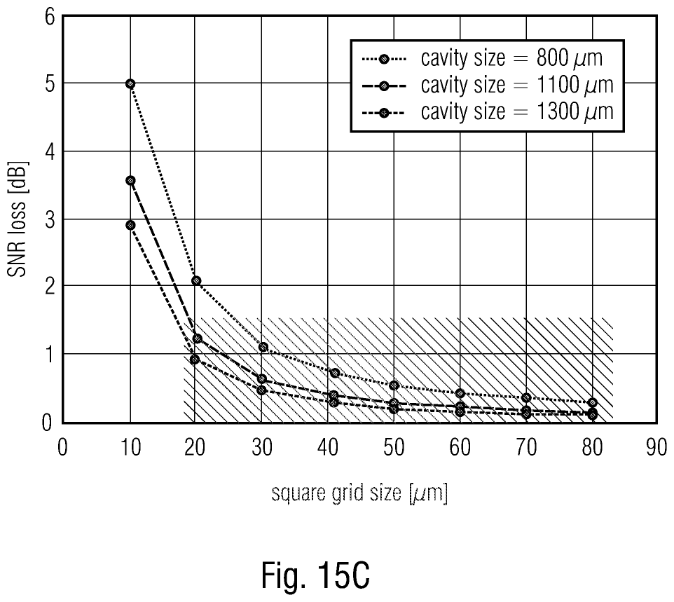

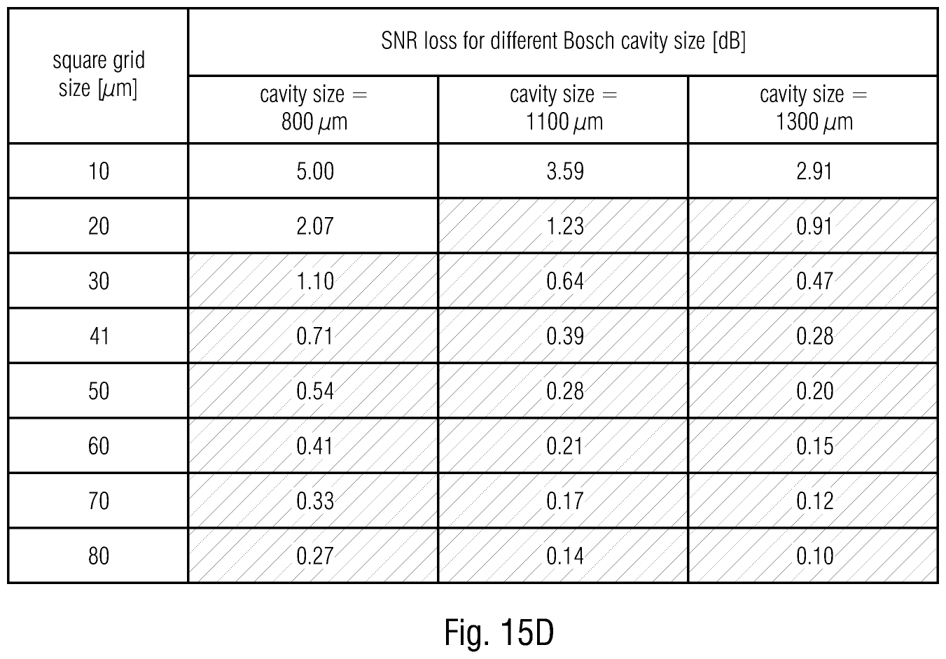

Tests and simulations were performed in order to verify the effectiveness of the environmental barrier chip 500. FIG. 15A shows a schematic perspective view of an environmental barrier chip 500 with an environmental barrier structure 220 attached to the first substrate surface 201. FIG. 15B shows a picture taken with a scanning electron microscope, the picture showing the upper surface (i.e. first substrate surface 201) of the environmental barrier chip 500, where the environmental barrier structure 220 is provided as a micro-machined mesh with square grids 223. Each of the square grids 223 may include a square grid size of x μm (i.e. the length is x μm, and the width is x μm).

The environmental barrier structure 220 is arranged above the first cavity 230. The cavity 230 may include a size of y μm. In case of a circular cavity 230, the size is defined as the diameter of the cavity 230.

FIG. 15C shows the correlation between the square grid size and the SNR loss in decibels (dB). The numbers are for descriptive purposes and are not limiting in any way. As can be seen, the smaller the square grid size, the higher the SNR loss. In other words, a smaller grid size leads to a higher SNR loss. The grey shaded box shows an optimal range, indicating that a square grid size of 18 μm or more is desirable.

FIG. 15D shows the correlation between the square grid size and the cavity size. The grey-shaded rows and columns indicate combinations that worked well. In other words, different cavity sizes resulted in similar trends with varied SNR loss values, in which a grid size of 10 μm can be excluded from the design because of too high SNR loss. A grid size of 20 μm in combination with a cavity size of 800 μm may be excluded.

Depending on the size of the cavity 230, the square grid size of an environmental barrier structure 220 shall be 20 μm or more in order to provide a good SNR while efficiently preventing environmental solid, gaseous and/or moist particles from passing the environmental barrier structure 220.

In the above described examples, the environmental barrier chip 500 and the MEMS microphone chip 605 were provided as discrete components. As an alternative, the environmental barrier structure 220 and at least a membrane structure of the MEMS microphone may be monolithically integrated into one common chip. Corresponding examples and embodiments shall be described in the following, with reference to FIGS. 16 to 20C.

The monolithic integration of an environmental barrier structure 220 and a MEMS sound transducer device (e.g., a microphone membrane or speaker membrane) into one single common chip may result in a MEMS microphone device 610 with a monolithically integrated environmental barrier structure 220. An exemplary embodiment is shown in FIG. 16.

The MEMS microphone device 610 may include a substrate structure 100. The substrate structure 100 may include a base substrate 200, which may be comparable to, or may be the same as, the above mentioned substrate 200. The substrate structure 100 may further include an additional substrate material layer 210, which may be comparable to, or may be the same as, the above mentioned additional material layer 210. The additional substrate material layer 210 may be deposited on the base substrate 200.

For example, the additional substrate material layer 210 may include a different etch characteristic than the base substrate 200. For example, the additional substrate material layer 210 and the base substrate 200 may include a high selectivity for one and the same etchant. Thus, the additional substrate material layer 210 may serve the purpose of an etch stop layer. For example, the additional substrate material layer 210 may include, tetraethyl orthosilicate, formally named tetraethoxysilane (TEOS).

The MEMS microphone device 610 may further include the microstructured micromechanical environmental barrier structure 220. The environmental barrier structure 220 may be configured to let a first amount of air pass through while preventing a second amount of at least one of moisture, liquid, oil and solid environmental particles from passing through.

Nanofibers 240 may be applied onto at least one of the first and second sides/surfaces 251, 252 of the micromechanical environmental barrier structure 220. The nanofibers 240 may combine to form an air permeable nanomesh or nanomembrane structure.

In addition to the environmental barrier structure 220, the MEMS microphone device 610 may include a MEMS sound transducer structure 120. The MEMS sound transducer structure 120 may include, or may be configured as, a membrane, in particular as a microphone membrane being configured to swing, resonate or vibrate, respectively, in response to impinging sound waves. The MEMS sound transducer structure 120 may be created, e.g. deposited, in the substrate structure 100. For example, the MEMS sound transducer structure 120 may be created, e.g. deposited, in the additional substrate material 210 of the substrate structure 100. The MEMS sound transducer structure 120 may be created by applying a microstructuring process.

As disclosed herein, the MEMS sound transducer structure 120 and the micromechanical environmental barrier structure 220 are both monolithically integrated in the substrate structure 100. For example, both the MEMS sound transducer structure 120 and the micromechanical environmental barrier structure 220 may be integrated in the additional substrate material layer 210.

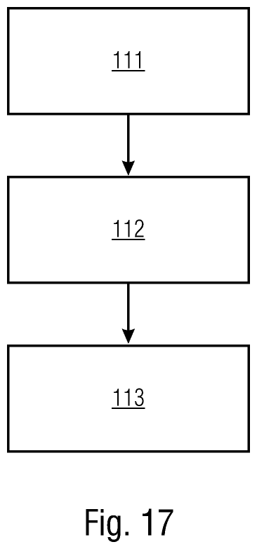

FIG. 17 shows a corresponding method for manufacturing a MEMS microphone device 610 with a monolithically integrated environmental barrier structure 220.

In block 111, a substrate structure 100 is provided, the substrate structure 100 including a base substrate 200 and an additional substrate material layer 210 deposited on the base substrate 200.

In block 112, a microstructured micromechanical environmental barrier structure 220 is created in the substrate structure 100 by applying a microstructuring process, where the microstructured micromechanical environmental barrier structure 220 is configured to let a first amount of air pass while preventing a second amount of at least one of moisture, liquid, oil and solid environmental particles from passing.

In block 113, a MEMS sound transducer structure 120 is created in the additional substrate material 210 of the substrate structure 100 by applying a microstructuring process.

The above mentioned embodiments can result in the MEMS sound transducer structure 120 and the microstructured micromechanical environmental barrier structure 220 being both monolithically integrated in the substrate structure 100.

The monolithic integration may, in general, be realized by different methods, such as:
Method 1: Creation of the environmental barrier structure 220 based on surface micromachining method prior to, or after, a typical processing sequence of creating a MEMS microphone.
Method 2: Direct structuring of the base substrate 200 in order to create an environmental barrier structure 220 in the base substrate 200.

The Method 1 for creating the environmental barrier structure 220 may generally be comparable to embodiments described above with reference to FIGS. 1 to 15D. Thus, the description of the formation of the environmental barrier structure 220 may apply for various embodiments disclosed herein.

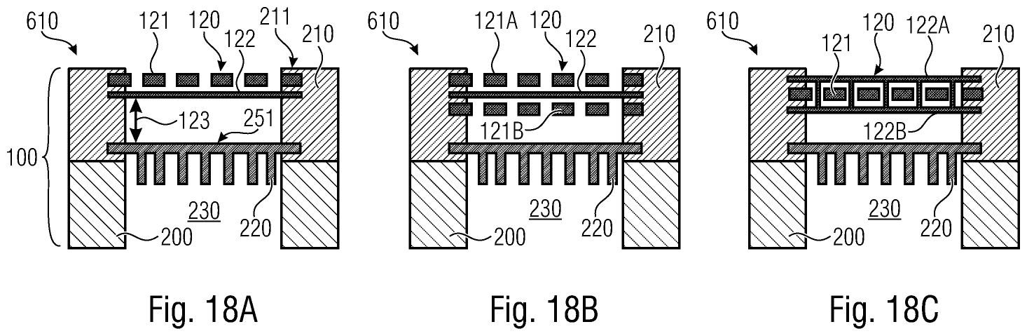

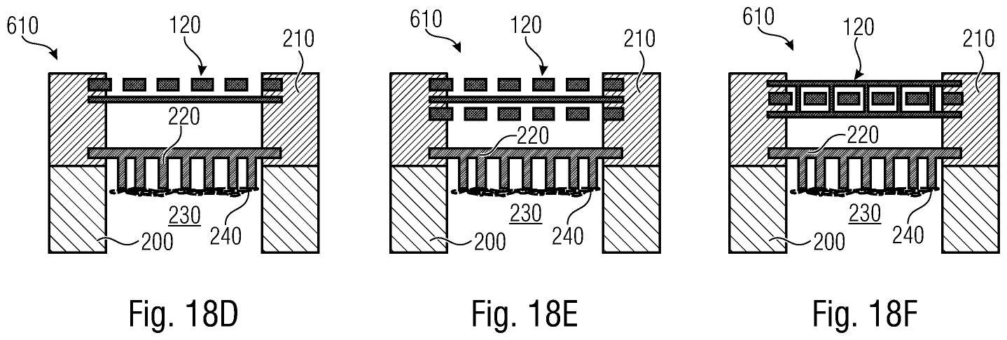

As mentioned above, the MEMS sound transducer structure 120 may include, or may be configured as, a microphone membrane. Different configurations of such sound transducer structures 120 may be possible to be monolithically integrated with the environmental barrier structure 220. FIGS. 18A to 18F show some possible different configurations. In each embodiment, the MEMS sound transducer structure 120 may be created by using a microstructuring process, e.g. by depositing the MEMS sound transducer structure 120 in or at the additional material layer 210.

FIG. 18A shows a possible configuration of a MEMS microphone device 610 in which the MEMS sound transducer structure 120 may be configured as a so-called Single Back Plate (SBP) structure. The MEMS sound transducer structure 120 includes one single backplate electrode 121 and a membrane 122 arranged in parallel to, and spaced apart from, the backplate electrode 121.

FIG. 18B shows a further possible configuration of a MEMS microphone device 610 in which the MEMS sound transducer structure 120 may be configured as a so-called Dual Back Plate (DBP) structure. It includes two parallel backplate electrodes 121A, 121B and a membrane 122 arranged in between.

FIG. 18C shows a further possible configuration of a MEMS microphone device 610 in which the MEMS sound transducer structure 120 may be configured as a so-called Sealed Dual Membrane (SDM) structure. It includes a first and a second membrane 122A, 122B with an electrode 121 arranged in between.

FIG. 18D shows a further possible configuration of a MEMS microphone device 610, which substantially corresponds to the SBP embodiment of FIG. 18A, but where nanofibers 240 may additionally be applied on at least one side of the environmental barrier structure 220 in order to improve the environmental protection level.

FIG. 18E shows a further possible configuration of a MEMS microphone device 610, which substantially corresponds to the DBP embodiment of FIG. 18B, but where nanofibers 240 may additionally be applied on at least one side of the environmental barrier structure 220 in order to improve the environmental protection level.

FIG. 18F shows a further possible configuration of a MEMS microphone device 610, which substantially corresponds to the SDM embodiment of FIG. 18C, but where nanofibers 240 may additionally be applied on at least one side of the environmental barrier structure 220 in order to improve the environmental protection level.

The above listed first method (‘Method 1’) may leave the used base substrate 200 unmodified. Instead, the environmental barrier structure 220 may be created on top of or above the base substrate 200, e.g., in the additional material layer 210. Creation of the environmental barrier structure 220 may be performed prior to the MEMS fabrication process for creating the MEMS sound transducer structure 120. A single anisotropic etching process, for instance a single Bosch etching process, may be employed.

As can be seen in FIGS. 18A to 18F, the environmental barrier structure 220 may be created (e.g. deposited) somewhere inside the additional material layer 210. The environmental barrier structure 220 may be created (e.g. deposited) on top of the additional material layer 210, as was described with reference to FIGS. 4A to 4C. The microstructured micromechanical environmental barrier structure 220 may be arranged in the additional substrate material layer 210.

Accordingly, and with continued reference to FIGS. 18A to 18F, providing the micromechanical environmental barrier structure 220 in the additional substrate material layer 210 may include arranging the microstructured micromechanical environmental barrier structure 220 in or on the additional substrate material layer 210, which may substantially correspond to the embodiments described above with reference to FIGS. 4A to 4C. However, the thickness of the additional substrate material layer 210 may be different. As exemplarily shown in FIGS. 18A to 18F, the additional substrate material layer 210 may include a thickness that may be substantially as large as the thickness of the base substrate 200. The additional substrate material layer 210 may include a smaller thickness. However, the thicker the additional substrate material layer 210 the higher the gap between the MEMS sound transducer structure 120 and the environmental barrier structure 220 (see reference numeral 123 in FIG. 18A), which allows the MEMS sound transducer structure 120 to freely oscillate without touching the environmental barrier structure 220.

With continued reference to FIGS. 18A to 18F, providing the microstructured micromechanical environmental barrier structure 220 in the additional substrate material layer 210 may further include applying an anisotropic etching process including an etching step for etching completely through the base substrate 200 until reaching the additional substrate material layer 210 such that a through hole 230 is created inside the base substrate 200, the through hole 230 being positioned opposite the microstructured micromechanical environmental barrier structure 220, which may substantially correspond to the embodiments as described above with reference to FIGS. 5A to 5C.

With continued reference to FIGS. 18A to 18F, the method may further include removing any of the additional substrate material layer 210 residing inside the through hole 230, i.e. underneath the environmental barrier structure 220, in order to expose the environmental barrier structure 220, which may correspond to the embodiments as described above with reference to FIGS. 5A to 5C.

The additional substrate material layer 210 above the environmental barrier structure 220 may be removed, e.g. by etching from an upper side 211 (FIG. 18A) of the additional material layer 210 down until reaching the upper surface 251 of the environmental barrier structure 220, which results in a cavity above the environmental barrier structure 220, in which the MEMS sound transducer structure 120 may be arranged. In some embodiments, the aforementioned through hole 230 may be created by etching completely through the base substrate 200 and the additional material layer 220.

According to Method 2 the initial base substrate 200 may be directly structured for creating the environmental barrier structure 220. The base substrate 200 may be structured by using an anisotropic double etching process, for example a double Bosch etching process. Different designs of the environmental barrier structure 220 may be formed by etching different forms and sizes of mesh structures or openings into the base substrate 200. For example, the mesh structures or openings may include various geometrical shapes including circular, rectangular or trapezoidal shapes, among others, being arranged in a grid.

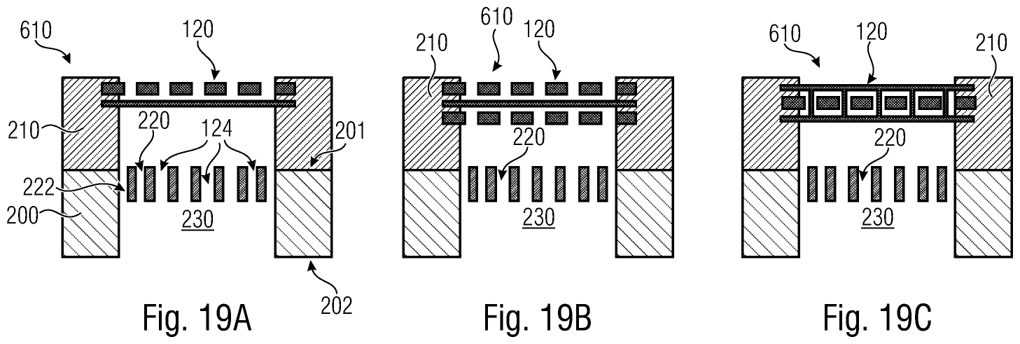

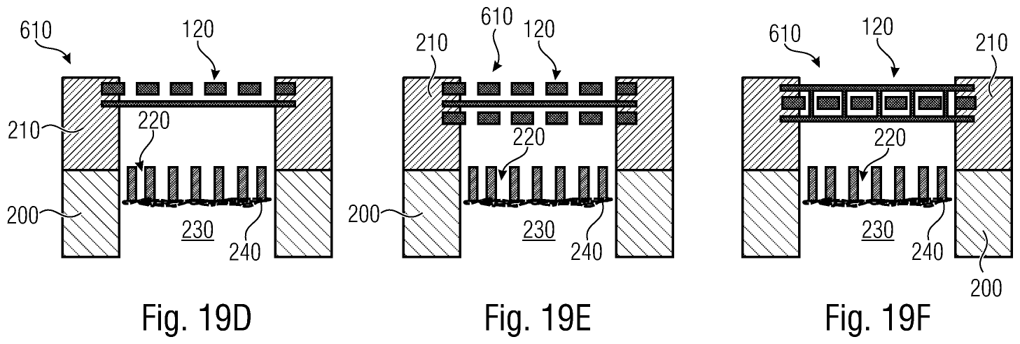

FIGS. 19A to 19F show some exemplary embodiments of a direct structuring of the base substrate 200 in order to create the environmental barrier structure 220. In other words, the microstructured micromechanical environmental barrier structure 220 may be structured into the base substrate 200.

The base substrate 200 may include a first substrate surface 201 that faces the additional substrate material layer 210 and an opposite second substrate surface 202 that faces away from the additional substrate material layer 210.

The herein described method may include applying a two-step anisotropic etching process (e.g. a double Bosch etch) for structuring the microstructured micromechanical environmental barrier structure 220 into the base substrate 200. The two-step etching process may include a first anisotropic etching step for anisotropically etching from the second substrate surface 202 towards the first substrate surface 201 so as to create the cavity 230 inside the base substrate 200. A non-removed substrate portion 222 (FIG. 19A) remains between the cavity 230 and the additional substrate material layer 210. Creating the cavity 230 may substantially correspond to the method as described above with reference to FIGS. 5A to 5C.

The two-step etching process may further include a second anisotropic etching step for anisotropically etching a plurality of perforations 124 into the base substrate 200, and in particular into the remaining substrate portion 222, such that the perforations extend between the first substrate side 201 and the cavity 230. As can be seen in FIGS. 19A to 19F, the remaining substrate portion 222 (FIG. 19A) is now perforated and may, therefore, provide the functionality of the environmental barrier structure 220.

The MEMS sound transducer structure 120 may be provided in at least one of the configurations as explained above with reference to FIGS. 18A to 18F, where additional nanofibers 240 may be applied onto the environmental barrier structure 220 to improve an environmental protection level. Accordingly, the MEMS sound transducer structure 120 may be provided in a SBP configuration with (FIG. 19D) or without (FIG. 19A) nanofibers 240. Accordingly, the MEMS sound transducer structure 120 may be provided in a DBP configuration with (FIG. 19E) or without (FIG. 19B) nanofibers 240. In some embodiments, the MEMS sound transducer structure 120 may be provided in a SDM configuration with (FIG. 19F) or without (FIG. 19C) nanofibers 240.

For both methods (Methods 1 and 2), the created environmental barrier structure 220 may be positioned underneath the MEMS sound transducer structure 120. In some embodiments, the environmental barrier structure 220 may be positioned above the MEMS sound transducer structure 120. As mentioned above, a higher gap 123 (FIG. 18A) between MEMS sound transducer structure 120 and the environmental barrier structure 220 may be realized by varying the thickness of the additional material layer 210, e.g. TEOS layer.

Irrespective of the method used (Method 1 or Method 2) creating the microstructured micromechanical environmental barrier structure 220 may be performed prior to creating the MEMS sound transducer structure 120, which may result in a stacked arrangement in which the environmental barrier structure 220 is closer to the base substrate 200 than the MEMS sound transducer structure 120.

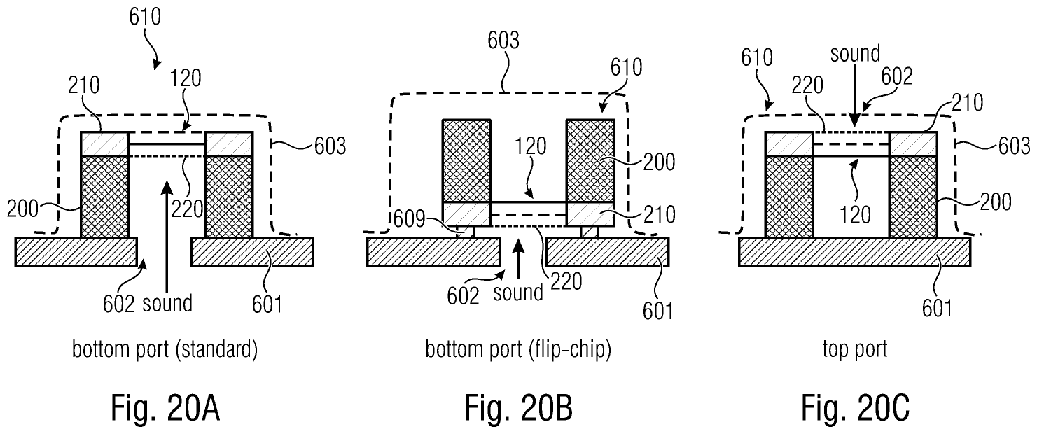

An example is shown in FIG. 20A, in which the environmental barrier structure 220 is closer to the base substrate 200 than the MEMS sound transducer structure 120, which may allow for placing the MEMS microphone device 610 including the monolithically integrated environmental barrier structure 220 above a sound port opening 602 provided in a carrier substrate 601 with the base substrate 200 facing the carrier substrate 601. The configuration in FIG. 20A may be referred to as a standard bottom-port configuration.

A lid 603 is schematically drawn in dashed lines in order to indicate that the MEMS microphone device 610 may be housed inside a package. For example, the MEMS microphone device 610 as depicted in FIG. 20A may be housed inside a package in one of the configurations as described above with reference to FIGS. 14A to 14E.

In an alternative, the creation of the micromechanical environmental barrier structure 220 may be performed after creating the MEMS sound transducer structure 120, which may result in a stacked arrangement in which the MEMS sound transducer structure 120 is closer to the base substrate 200 than the environmental barrier structure 220.

Different examples are shown in FIGS. 20B and 20C, where the MEMS sound transducer structure 120 is closer to the base substrate 200 than the environmental barrier structure 220. As shown in FIG. 20B, the MEMS microphone device 610 including the monolithically integrated environmental barrier structure 220 may be placed above a sound port opening 602 provided in a carrier substrate 601 with the additional material layer 210 facing the carrier substrate 601. The MEMS microphone device 610 may be attached to the carrier substrate 601, e.g. by using solder balls 609 or the like. The configuration in FIG. 20B may be referred to as a flip-chip bottom-port configuration.

A lid 603 is schematically drawn in dashed lines in order to indicate that the MEMS microphone device 610 may be housed inside a package. For example, the MEMS microphone device 610 as depicted in FIG. 20B may be housed inside a package in one of the configurations as described above with reference to FIGS. 14A to 14E.

As shown in FIG. 20C, the MEMS microphone device 610 including the monolithically integrated environmental barrier structure 220 may be arranged on a carrier substrate 601 inside a package, underneath a lid 603, where the sound port opening 602 is provided in the lid 603, which allows for arranging the MEMS microphone device 610 on the carrier substrate 601 with the base substrate 200 facing the carrier substrate 601. The configuration of FIG. 20C may be referred to as a top port configuration. For example, the MEMS microphone device 610 as depicted in FIG. 20C may be housed inside a package in one of the configurations as described above with reference to FIGS. 14A to 14E.

Summarizing, the herein described disclosure provides for manufacturing methods and integration methods for MEMS-based environmental barriers 220, as well as for a monolithic integration of an environmental barrier 220 with a MEMS sound transducer device 120. The present disclosure further provides for a device separation concept for packaging purposes.

Although some aspects have been described in the context of an apparatus, these aspects may represent a description of the corresponding method, where a block or device corresponds to a method step or a feature of a method step. Analogously, aspects described in the context of a method step may represent a description of a corresponding block or item or feature of a corresponding apparatus.

While this disclosure has been described with reference to illustrative embodiments, this description is not intended to be construed in a limiting sense. Various modifications and combinations of the illustrative embodiments, as well as other embodiments of this disclosure, are contemplated in reference to the description.

1. A method for manufacturing a microelectronic mechanical system MEMS microphone device monolithically integrated with an environmental barrier structure, the method comprising:
providing a substrate structure comprising a base substrate and an additional substrate material layer deposited on the base substrate;
creating a microstructured micromechanical environmental barrier structure in the substrate structure using a microstructuring process, wherein the microstructured micromechanical environmental barrier structure is configured to let a first amount of air pass through while preventing a second amount of at least one of moisture, liquid, oil or solid environmental particles from passing through; and
creating a MEMS sound transducer structure in the additional substrate material layer using a microstructuring process resulting in both the MEMS sound transducer structure and the microstructured micromechanical environmental barrier structure being monolithically integrated in the substrate structure.

2. The method according to claim 1, wherein the microstructured micromechanical environmental barrier structure is located in the additional substrate material layer.

3. The method according to claim 2, wherein providing the microstructured micromechanical environmental barrier structure in the additional substrate material layer further comprises:
arranging the microstructured micromechanical environmental barrier structure on the additional substrate material layer;
applying an anisotropic etching process further comprising:
etching completely through the base substrate until reaching the additional substrate material layer such that a through hole is created inside the base substrate, the through hole being positioned opposite the microstructured micromechanical environmental barrier structure; and
removing the additional substrate material layer residing inside the through hole in order to expose the environmental barrier structure.

4. The method according to claim 1, wherein the microstructured micromechanical environmental barrier structure is structured into the base substrate.

5. The method according to claim 4,
wherein the base substrate comprises a first substrate surface facing the additional substrate material layer and a second substrate surface opposite the first substrate surface and facing away from the additional substrate material layer, and
wherein structuring the microstructured micromechanical environmental barrier structure into the base substrate further comprises applying an anisotropic etching process further comprising:
a first etching step for anisotropically etching from the second substrate surface towards the first substrate surface to create a cavity inside the base substrate; and
a second etching step for anisotropically etching a plurality of perforations into the base substrate, the perforations extending between the first substrate surface and the cavity.

6. The method according to claim 1, wherein the microstructured micromechanical environmental barrier structure is created prior to creating the MEMS sound transducer structure, resulting in a stacked arrangement in which the environmental barrier structure is closer to the base substrate than the MEMS sound transducer structure.

7. The method according to claim 1, wherein the microstructured micromechanical environmental barrier structure is created after creating the MEMS sound transducer structure, resulting in a stacked arrangement in which the MEMS sound transducer structure is closer to the base substrate than the environmental barrier structure.

8. The method according to claim 1, wherein the microstructured micromechanical environmental barrier structure is formed as at least one of a perforated air permeable membrane or an air permeable mesh.

9. The method according to claim 1, further comprising applying nanofibers onto the microstructured micromechanical environmental barrier structure, wherein the nanofibers combine to form an air permeable nanofibrous membrane structure.

10. The method according to claim 9, wherein the nanofibers are applied on at least one of a first side or a second side of the microstructured micromechanical environmental barrier structure.

11. The method according to claim 9, wherein applying the nanofibers comprises at least one of:
arranging an adhesion promotion layer between the nanofibers and the microstructured micromechanical environmental barrier structure;
increasing a surface roughness of the microstructured micromechanical environmental barrier structure; or
applying a three-dimensional modification to the microstructured micromechanical environmental barrier structure, for improving an adhesion between the nanofibers and the microstructured micromechanical environmental barrier structure.

12. The method according to claim 9, further comprising applying a surface chemistry modification to the applied nanofibers by depositing at least one of:
organic self-assembled monolayers,
stearic acid-based modifiers, or
nanoparticles
onto the nanofibers for lowering a surface energy of the nanofibers resulting in an increased hydrophobicity.

13. The method according to claim 12, wherein the organic self-assembled monolayers include at least one of:
Perfluorodecyltrichlorosilane (FDTS),
Heptadecafluoro-1,1,2,2-tetrahydrodecyltrichlorosilane (HDFS),
Tridecafluoro-1,1,2,2-tetrahydrooctyltrichlorosilane (FOTS),
Octadecyltrichlorsilane (ODTS),
Methyltrimethoxysilane (MTMS),
Bis(trimethylsilyl)amine or hexamethyldisilazane (HMDS),
(3-Aminopropyl)triethoxysilane (APTES),
Dichlorodimethylsilane (DDMS),
Octadecyltrimethoxysilane (OTMS),
Ethyltriethoxysilane (ETES), or
1H,1H,2H,2H-perfluorooctyltriethoxysilane (HFOTES).

14. The method according to claim 1, wherein creating the MEMS sound transducer structure comprises forming at least one of:
a single backplate sound transducer structure comprising a single backplate electrode and a membrane arranged in parallel to, and spaced apart from, the backplate electrode;
a dual backplate sound transducer structure comprising two parallel backplate electrodes and a membrane arranged in between; or
a sealed dual-membrane sound transducer structure comprising a first and a second membrane with an electrode arranged in between.

15. A microphone device comprising:
a microelectronic mechanical system (MEMS) microphone device monolithically integrated with an environmental barrier structure, further comprising:
a substrate structure comprising a base substrate and an additional substrate material layer deposited on the base substrate;
a micromechanical environmental barrier structure microstructured in the substrate structure, wherein the micromechanical environmental barrier structure is configured to let a first amount of air pass through while preventing a second amount of at least one of moisture, liquid, oil or solid environmental particles from passing through; and
a MEMS sound transducer structure in the additional substrate material layer, wherein both the MEMS sound transducer structure and the micromechanical environmental barrier structure are monolithically integrated in the substrate structure.

16. The microphone device according to claim 15, wherein the micromechanical environmental barrier structure is located in the additional substrate material layer.

17. The microphone device according to claim 15, further comprising nanofibers located on the micromechanical environmental barrier structure, wherein the nanofibers combine to form an air permeable nanofibrous membrane structure.

18. The microphone device according to claim 17, wherein the nanofibers are located at least one of a first side or a second side of the micromechanical environmental barrier structure.

19. A microelectronic mechanical system (MEMS) microphone device, comprising:
a substrate structure comprising a base substrate and an additional substrate material layer deposited on the base substrate;
a micromechanical environmental barrier structure microstructured in the substrate structure, wherein the micromechanical environmental barrier structure is configured to let a first amount of air pass through while preventing a second amount of at least one of moisture, liquid, oil or solid environmental particles from passing through;
a MEMS sound transducer structure in the additional substrate material layer, wherein both the MEMS sound transducer structure and the micromechanical environmental barrier structure are monolithically integrated in the substrate structure; and
nanofibers located on the micromechanical environmental barrier structure, wherein the nanofibers combine to form an air permeable nanofibrous membrane structure.

20. The MEMS microphone device according to claim 19, wherein the micromechanical environmental barrier structure is structured into the base substrate.
